(19) United States
(12) Patent Application Publication
(10) Pub. No.: US 2007/0031598 A1
(43) Pub. Date: Feb. 8, 2007

(54) Method for depositing silicon-containing films

(76) Inventors: Yoshikazu Okuyama, Scotts Valley, CA (US); Jon S. Owyang, San Jose, CA (US); Helmuth Treichel, Milpitas, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/482,782

(22) Filed: Jul. 7, 2006

Related U.S. Application Data
(60) Provisional application No. 60/697,763, filed on Jul. 8, 2005.

(51) Int. Cl. C23C 16/00

(52) U.S. Cl. 427/248.1

(57) ABSTRACT

Methods for forming silicon containing films using silylamine moieties are disclosed. In some embodiments, silylamine moieties are employed to deposit silicon-nitrogen, silicon-oxygen, or silicon-nitrogen-oxygen materials at temperatures of less than 550° C. In some embodiments methods are practiced within process chambers adapted to contain a single substrate as well as within process chambers adapted to contain a plurality of substrates, where the silylamine moieties are conveyed to the chambers in across flow type manner.

### CROSS REFERENCE TO RELATED APPLICATIONS

This application claims the benefit of, and priority to, of U.S. Provisional Patent Application Ser. No. 60/697,763 filed on Jul. 8, 2005, entitled “Method for Depositing Silicon-Containing Films Using ALD” the entire disclosure of which is incorporated herein by reference.

### FIELD OF THE INVENTION

The present invention relates generally to methods for depositing silicon containing films on the surface of a substrate. Such silicon-containing films comprise silicon-nitrogen, silicon-oxygen, and silicon-nitrogen-oxygen dielectric materials used in the processing of semiconductors. More specifically, embodiments of the present invention provide use of silylamine moieties in the deposition of the silicon containing films carried out at low temperatures, preferably less than approximately 550° C.

### BACKGROUND OF THE INVENTION

Silicon nitride, silicon dioxide, and silicon oxynitride are dielectric materials widely used in the manufacture of semiconductor devices. These films are typically deposited from silicon sources such as silane (SiH₄), disilane (Si₂H₆), dichlorosilane (DCS) (SiCl₂H₂), and others with various reactant sources such as ammonia (NH₃), oxygen (O₂), ozone (O₃), nitrous oxide (N₂O), nitrogen dioxide (NO₂), nitric oxide (NO), and others depending on the desired material composition. The deposition temperatures of these processes are typically greater than 600° C. The high speed requirements of advanced semiconductor devices dictate that the overall thermal budget of the device manufacture be lowered. Several new silicon precursors have been developed to address the need for lower temperature dielectric deposition. Silicon tetraiodide can be used to deposit silicon nitride at temperatures between 400° C. and 500° C. However, this precursor is a solid at room temperature and produces a by-product of NH₄I that condenses on cool surfaces and causes particle problems. Hexachlorodisilane (HCD) (Si₂CL₆) can be used to form silicon nitride below 600° C., however, this precursor produces a by-product of NH₄Cl that condenses on cool surfaces and causes particle problems. Finally, an aminosilane compound such as bis(t-butylamino silane) (BTBAS) (SiC₈N₂H₂₂) is a halogen-free precursor that can be reacted with O₂, N₂O, or NH₃ to form the various dielectric materials of interest, but only at temperatures greater than about 550° C. Generally, materials formed with this precursor are not of sufficient quality for wide use in the manufacture of semiconductor devices. It is clear that the development of a new precursor and method for depositing dielectric materials at a low temperature without the problems of forming condensable by-products and incorporation of unwanted moieties into the film is desired.

New classes of precursors have been investigated including aminosilanes, silazanes, silyl alkyl compounds. However, these precursors contain carbon moieties that can incorporate carbon into the deposited material and degrade the dielectric properties of the film. Also, other classes of precursors have been investigated including silylamines using thermal chemical vapor deposition (CVD) techniques. Since the silylamines do not contain carbon, their dielectric properties are superior to the various aminosilanes referenced above. However, the CVD techniques were practical only at process temperatures of greater than 550° C., and the resultant silicon containing films are of poor quality. It is clear that the development of a method for depositing dielectric materials at a low temperature (for example <550° C.) is desired.

### BRIEF SUMMARY OF THE INVENTION

In general, the inventors have discovered methods that provide for the deposition of silicon containing dielectric materials. The dielectric materials will find uses in the manufacture of semiconductor structures such as spacers, etch stops, hard masks, gates dielectrics, capacitor dielectrics, and the like. The methods provide for the deposition of the dielectric materials using silylamine precursors at low temperatures.

In some embodiments of the present invention, the inventors have discovered methods that provide for the deposition of a silicon-nitrogen dielectric material (such as silicon nitride) by reacting a silylamine precursor with a nitrogen containing reactant at a temperature of equal to or less than 550° C. The methods are practiced within process chambers adapted to contain a single substrate as well as within process chambers adapted to contain a plurality of substrates, and are carried out using chemical vapor deposition (CVD) techniques, and in an alternative embodiment by atomic layer deposition (ALD) techniques.

In other embodiments of the present invention, the inventors have discovered methods that provide for the deposition of a silicon-oxygen dielectric material (such as silicon dioxide) by reacting a silylamine precursor with an oxygen containing reactant at a temperature of equal to or less than 550° C. The methods are practiced within process chambers adapted to contain a single substrate as well as within process chambers adapted to contain a plurality of substrates, and are carried out using chemical vapor deposition (CVD) techniques, and in an alternative embodiment by atomic layer deposition (ALD) techniques.

In yet other embodiments of the present invention, the inventors have discovered methods that provide for the deposition of a silicon-nitrogen-oxygen dielectric material (such as silicon oxynitride) by reacting a silylamine precursor with an oxygen containing reactant and a nitrogen containing reactant at a process temperature of equal to or less than 550° C. The methods are practiced within process chambers adapted to contain a single substrate as well as within process chambers adapted to contain a plurality of substrates and are carried out using chemical vapor deposition (CVD) techniques, and in an alternative embodiment by atomic layer deposition (ALD) techniques.

In another aspect, methods of forming a silicon containing film on the surface of one or more substrates are provided, characterized in that: a silylamine moiety and one or more reactant precursors are reacted in a process chamber by flowing the silylamine moiety and the one or more reactant precursors, either concurrently or sequentially, across a top surface of the one or more substrates to form a film thereon.

### BRIEF DESCRIPTION OF THE DRAWING

These and various other features and advantages of the present invention will be apparent upon reading of the following detailed description in conjunction with the accompanying drawings and the appended claims provided below, where:

FIG. 1 is a cross-sectional view of one example of a vertical batch thermal processing system having across-flow injector system which may be employed to carry out methods according to some embodiments of the present invention;

FIG. 2 illustrates a cross-sectional side view of a portion of the thermal processing system of FIG. 1 showing positions of injector orifices in relation to the liner and of exhaust slots in relation to the wafers according to some embodiments of the present invention;

FIG. 3 is a plan view of a portion of the thermal processing system of FIG. 1 taken along the line A-A of FIG. 1 showing gas flow from orifices of a primary and a secondary injector across a wafer and to an exhaust port according to some exemplary embodiments of the present invention;

FIG. 4 depicts a plan view of a portion of the thermal processing system of FIG. 1 taken along the line A-A of FIG. 1 showing gas flow from orifices of a primary and a secondary injector across a wafer and to an exhaust port according to other embodiments of the present invention;

FIG. 5 is a plan view of a portion of the thermal processing system of FIG. 1 taken along the line A-A of FIG. 1 showing gas flow from orifices of a primary and a secondary injector across a wafer and to an exhaust port according to yet another embodiment of the present invention;

FIG. 6 illustrates deposition rate and WIWNU as a function of deposition temperature for oxide films deposited in a single wafer thermal processing apparatus by chemical vapor deposition according to embodiments of the present invention; and

FIG. 7 depicts silicon nitride deposition rate as a function of deposition temperature for silicon nitride films deposited in a batch thermal processing apparatus by chemical vapor deposition according to embodiments of the present invention.

### DETAILED DESCRIPTION OF THE INVENTION

In general, the inventors have discovered methods that provide for the deposition of silicon containing dielectric materials. The dielectric materials will find uses in the manufacture of semiconductor structures such as spacers, etch stops, hard masks, gates dielectrics, capacitor dielectrics, and the like. In some embodiments the methods provide for the deposition of the dielectric materials using silylamine precursors by chemical vapor deposition (CVD) . In alternative embodiments, atomic layer deposition (ALD) is used. In one embodiment of the present invention, a first class of the silylamines has the general formula:
HₘN(SiH₃)ₙ
where n is an integer from 1 to 3 and m is equal to 3−n. In another embodiment, silylamine precursors are provided having the general formula:
HₘN(Si₂H₅)ₙ
where n is an integer from 1 to 3 and m is equal to 3−n. In the present invention, the term “silylamine(s)” will be understood to include all members of both classes of these compounds.

In a general embodiment of the present invention, silylamine is used as a precursor to deposit a silicon containing dielectric film on a substrate. In some embodiments, silicon oxide films are formed with silylamine precursors of the above formulas, by chemical vapor deposition or atomic vapor deposition, said deposition processes being carried out at a deposition temperature in the range of approximately 150-550° C. In other embodiments the deposition temperature is in the range of approximately 150-450° C. In additional embodiments, the deposition temperature is in the range of approximately 500-520° C.

In other embodiments, silicon nitride films are formed with silylamine precursors of the above formulas, by chemical vapor deposition or atomic layer deposition, said deposition processes being carried out at a deposition temperature in the range of approximately 300-800° C., and preferably at 550° C. and below. In other embodiments the deposition temperature is in the range of approximately 500-520° C.

In some embodiments, deposition is carried out using chemical vapor deposition (CVD) techniques. A process chamber is provided that is adapted to hold at least one substrate. Silylamine is used as a precursor to deposit a silicon containing dielectric film on the substrate(s). During CVD, silylamine and other reactant precursors are injected together into a chamber, where the precursors react and form a film or layer of desired material on the surface of one or more substrates. During deposition the substrate(s) is controlled to a desired temperature, typically 550° C. or less, and the pressure in the process chamber is controlled to a desired pressure, typically between 0.01 mTorr and 760 Torr. The reaction of the reactant precursors with the silylamine forms a silicon-nitrogen, silicon-oxygen, silicon-nitrogen-oxygen film, or the like on the substrate(s) depending on the chemical nature of the reactant(s). Examples of suitable reactant precursors for reaction with the silylamine precursor include, but are not limited to: ammonia (NH₃), hydrazine (N₂H₄), water vapor (H₂O), oxygen (O₂), ozone (O₃), nitrous oxide (N₂O), nitric oxide (NO), nitrogen dioxide (NO₂), and the like.

In other embodiments deposition is carried out using atomic layer deposition (ALD) techniques. A process chamber is provided that is adapted to hold at least one substrate. The substrate is controlled to a desired temperature, typically 550° C. or less, and the pressure in the process chamber is controlled to a desired pressure, typically between 0.01 mTorr and 760 Torr. The silylamine precursor is introduced into the process chamber and allowed to form a monolayer on the surface of the substrate(s). Excess amounts of the silylamine are removed from the process chamber. One or more reactants are then introduced into the process chamber either sequentially or simultaneously and allowed to react with the monolayer of the silylamine that was previously formed on the substrate(s). Films are formed comprised of silicon-nitrogen, silicon-oxygen, or silicon-nitrogen-oxygen film on the substrate(s) depending on the chemical nature of the reactant(s). Excess amounts of the reactant(s) are removed from the process chamber. This sequence is repeated until the desired thickness of the dielectric material is deposited on the substrate(s). Examples of suitable reactants include, but are not limited to: ammonia (NH₃), hydrazine (N₂H₄), water vapor (H₂O), oxygen (O₂), ozone (O₃), nitrous oxide (N₂O), nitric oxide (NO), nitrogen dioxide (NO₂), and the like.

In one embodiment of the present invention, a silylamine such as N(SiH₃)₃ designated as “trisilylamine” (TSA) is used as a precursor to deposit a silicon-nitrogen containing dielectric film on a substrate. In this embodiment, the process chamber is adapted to hold a single substrate. The substrate is controlled to a desired temperature, typically 550° C. or less, and most preferably 400° C. or less. The pressure in the process chamber is controlled to a desired pressure, typically between 0.01 mTorr and 760 Torr, most preferably less than 10 Torr. In an ALD embodiment, TSA precursor is introduced into the process chamber and allowed to form a monolayer on the surface of the substrate(s). Excess amounts of TSA precursor are removed from the process chamber. A nitrogen containing reactant is conveyed into the process chamber and allowed to react with the monolayer of the TSA that was previously formed on the substrate(s). This sequence is repeated until the desired thickness of the silicon-nitrogen dielectric material is deposited on the substrate(s). In a CVD embodiment, TSA precursor and the nitrogen containing reactant are conveyed to the process chamber concurrently. Examples of suitable nitrogen containing reactants comprise ammonia (NH₃), hydrazine (N₂H₄), azides, and the like. The reaction of the nitrogen containing reactant with TSA forms a silicon-nitrogen dielectric film on the substrate(s).

An alternative embodiment to deposit a silicon-nitrogen containing dielectric film on a substrate is illustrated. A vertical furnace is used to hold a plurality of silicon wafers, preferably 300 mm wafers. Typically the wafers number between 1 and 100 for a single batch process. One embodiment of a preferred vertical batch thermal processing furnace technology includes “across-flow” technology as described in detail in U.S. patent application Ser. Nos. 10/521,619 and 10/946,849 which are hereby incorporated by reference in their entirety. The wafers are loaded into the furnace and the pressure is reduced to <10,000 mTorr, preferably between 500 and 5000 mTorr. The temperature is controlled to between 100° C. and 550° C. This embodiment of the method may be carried out using CVD, or ALD techniques.

When using a CVD process, deposition is initiated by conveying to the process chamber TSA and a nitrogen containing reactant, such as NH₃. The flowrate of TSA is in the range of approximately 1 sccm and 100 sccm, and the flowrate of NH₃ is in the range of approximately 50 sccm and 10,000 sccm. TSA and NH₃ react and form a layer of silicon nitride on the surface of one or more substrates. The CVD process is carried out until a desired thickness of the film is achieved. This process sequence can be used to deposit high quality silicon-nitrogen dielectric films with a within-wafer uniformity of <3.0% 3-sigma, a wafer-to-wafer uniformity of <3.0% 3-sigma, a silicon to nitrogen ratio [Si:N] of between 0.65 and 0.85, and a refractive index of between 1.9 and 2.1.

When using an ALD process, deposition is initialed by flowing between 1 sccm and 100 sccm of “trisilylamine” (TSA) and allowed to form a monolayer on the wafers. Excess amounts of TSA are removed by purging with N₂. A nitrogen containing reactant such as NH₃ is introduced to the process chamber by flowing between 50 sccm and 10,000 sccm of NH₃. The NH₃ reacts with the monolayer of TSA to form a silicon-nitrogen dielectric layer. Excess amounts of the NH₃ are removed by purging with N₂. Typically, total gas flows throughout the process are less than 20,000 sccm. This results in the deposition of a silicon-nitrogen dielectric layer with an effective deposition rate of between 0.2 and 5.0 A per cycle. This sequence is repeated until the desired thickness of the silicon-nitrogen dielectric film is deposited. The pressure in the process chamber is then increased to one atmosphere and the wafers are removed from the process chamber.

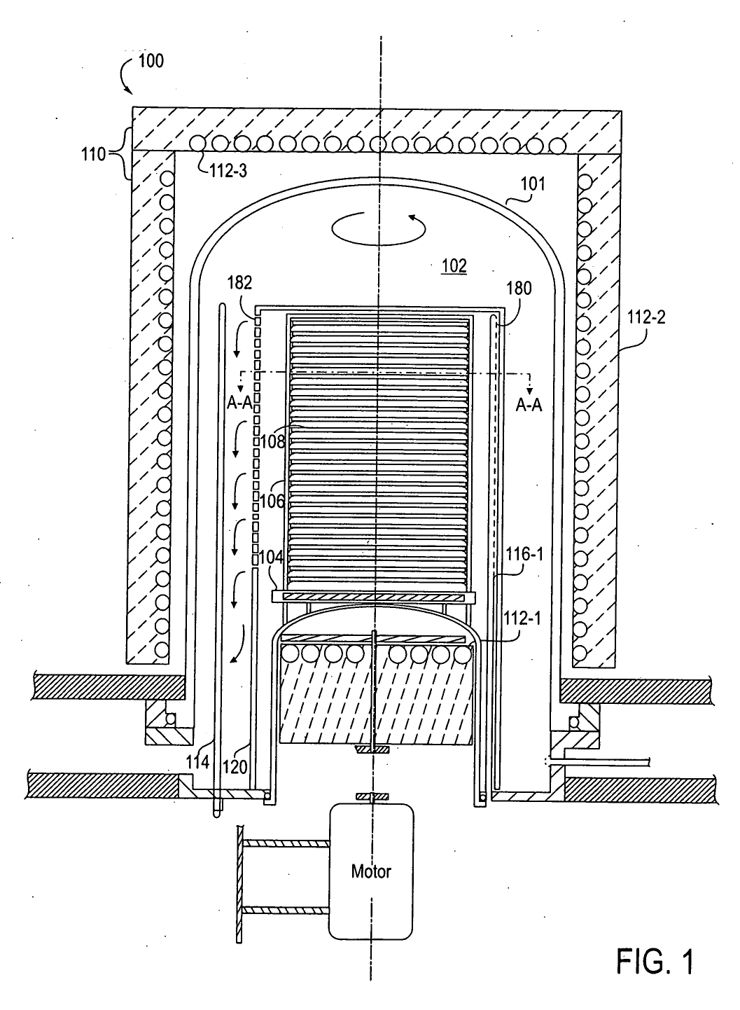

Referring to FIGS. 1 to 5, one embodiment of a vertical batch thermal processing system 100 is shown which may be used to carry out embodiments of the present invention. Of particular advantage, the system 100 provides for delivering precursors in an “across-flow” manner according to embodiments of the present invention. Conveying the precursor(s) to the substrate(s) in a cross-flow manner generally comprises injecting precursor(s) near one peripheral region of the substrate, and flowing the precursor(s) across the surface of the substrate, where the precursor(s) then exits at an opposite peripheral region of the substrate.

The batch thermal system 100 may be operated in CVD or ALD mode, and thus may be utilized for these two different embodiments of the present invention. In general, the system 100 generally comprises a vessel 101 that encloses a volume to form a process chamber 102 having a support 104 adapted for receiving a carrier or boat 106 with a batch of wafers 108 held therein, and heat source or furnace 110 having a number of heating elements 112-1, 112-2 and 112-3 (referred to collectively hereinafter as heating elements 112) for raising the temperature of the wafers to the desired deposition temperature for thermal processing. The thermal processing system 100 typically includes one or more injectors for conveying a fluid, such as a gas or vapor, into the process chamber 102 for processing and/or cooling the wafers 108, and one or more purge ports or vents for conveying a gas to purge the process chamber and/or to cool the wafers. A liner 120 may be used to increase the concentration of processing gas or vapor near the wafers 108 in a region or process zone in which the wafers are processed, and reduces contamination of the wafers from flaking or peeling of deposits that can form on interior surfaces of the process chamber 102. Processing gas or vapor exits the process zone through exhaust ports or slots 182 in the chamber liner 120.

In some embodiments, of particular advantage, injectors 216 are used in the thermal processing system 100. The injectors 116 are distributive or across(X)-flow injectors in which reactant precursors or other gas or vapor is introduced through injector openings or orifices 180 on one side of the wafers 108 and boat 106 and caused to flow across the surfaces of the wafers in a laminar flow type manner to exit exhaust ports or slots 182 in the chamber line 120 on opposite the side.

Additionally, X-flow injectors 116 can serve other purposes, including the injection of gases for cool-down (e.g., helium, nitrogen, hydrogen) for forced convective cooling between the wafers 108. Use of X-flow injectors 116 results in a more uniform cooling between wafers 108 whether disposed at the bottom or top of the stack or batch and those wafers that are disposed in the middle, as compared with earlier up-flow or down flow configurations. Preferably, the injector orifices 180 are sized, shaped and position to provide a spray pattern that promotes forced convective cooling between the wafers 108 in a manner that does not create a large temperature gradient across the wafer.

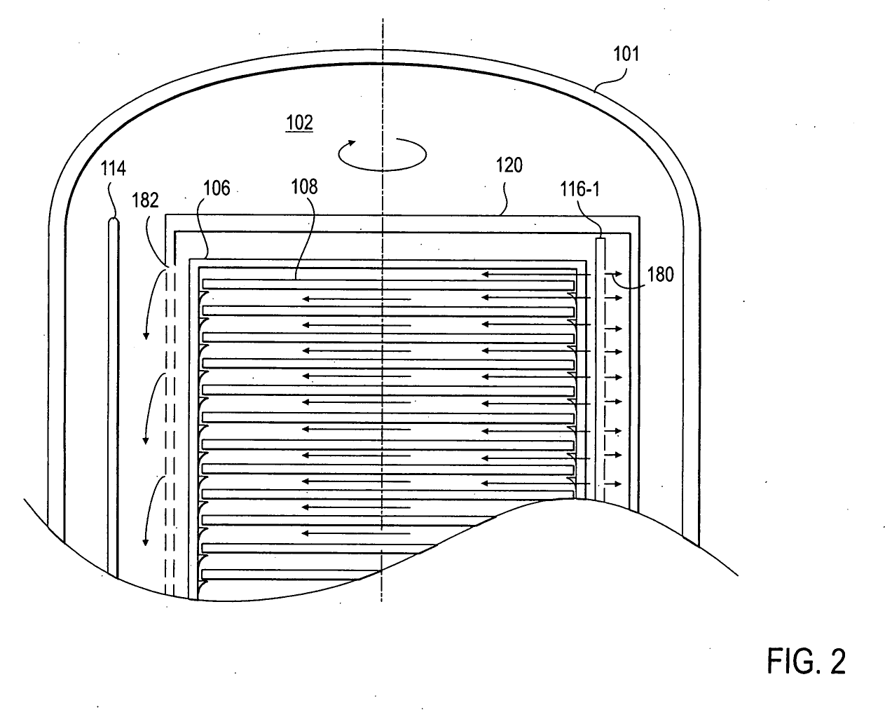

FIG. 2 is a cross-sectional side view of a portion of the thermal processing system 100 of FIG. 1 showing illustrative portions of the injector orifices 180 in relation to the chamber liner 120 and the exhaust slots 182 in relation to the wafers 108.

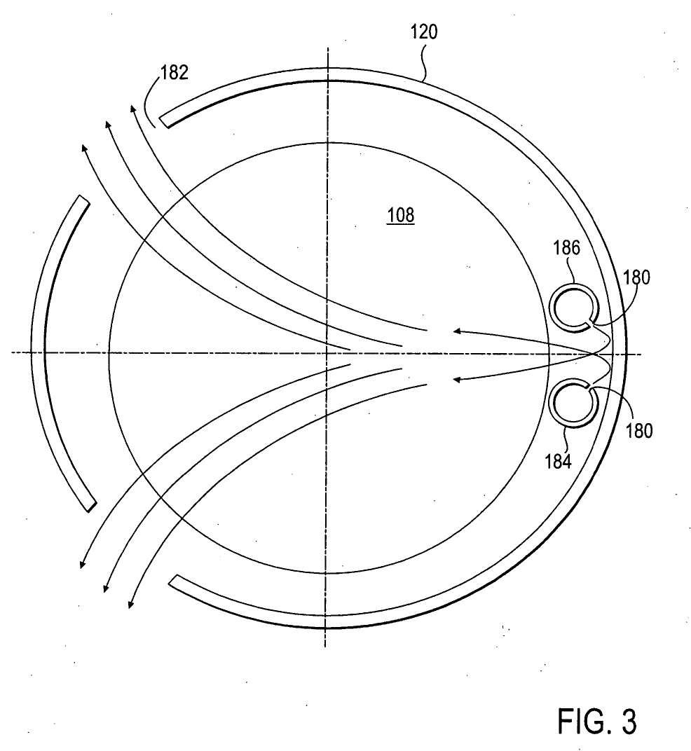

FIG. 3 is a plan view of a portion of the thermal processing apparatus 100 of FIG. 1 taken along the line A-A of FIG. 1. In this embodiment the injector 116 is comprised of primary and secondary injectors. FIG. 3 illustrates laminar gas flow from orifices 180-1 and 180-2 of primary and secondary injectors 184, 186 respectively, across an illustrative one of the wafers 108 and to exhaust slots 182-1 and 182-2. It should be noted that the position of the exhaust slot 182 as shown in FIG. 1 have been shifted from the position of exhaust slots 182-1 and 182-2 shown in FIG. 3 to allow illustration of the exhaust slot and injector 116 in a single a cross-sectional view of a thermal processing apparatus. It should also be noted that the dimensions of the injectors 184, 186, and the exhaust slots 182-1 and 182-2 relative to the wafer 108 and the chamber liner 120 have been exaggerated to more clearly illustrate the gas flow from the injectors to the exhaust slots.

Also as shown in FIG. 3, the process gas or vapor is initially directed away from the wafers 108 and toward the liner 120 to promote mixing of the process gas or vapor before it reaches the wafers. This configuration of orifices 180-1 and 180-2 is particularly useful for processes or recipes in which different reactants are introduced from each of the primary and secondary injectors 184, 186, for example to form a multi-component film or layer.

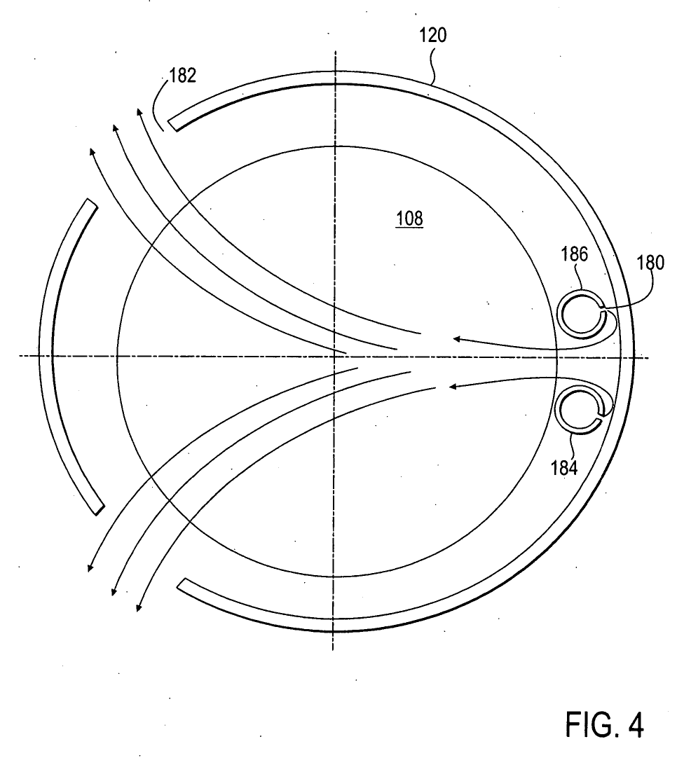

FIG. 4 is another plan view of a portion of the thermal processing system 100 of FIG. 1 taken along the line A-A of FIG. 1 showing an alternative gas flow path from the orifices 180 of the primary and secondary injector 184, 186, across an illustrative on of the wafer 108 and to the exhaust slots 182 according to another embodiment.

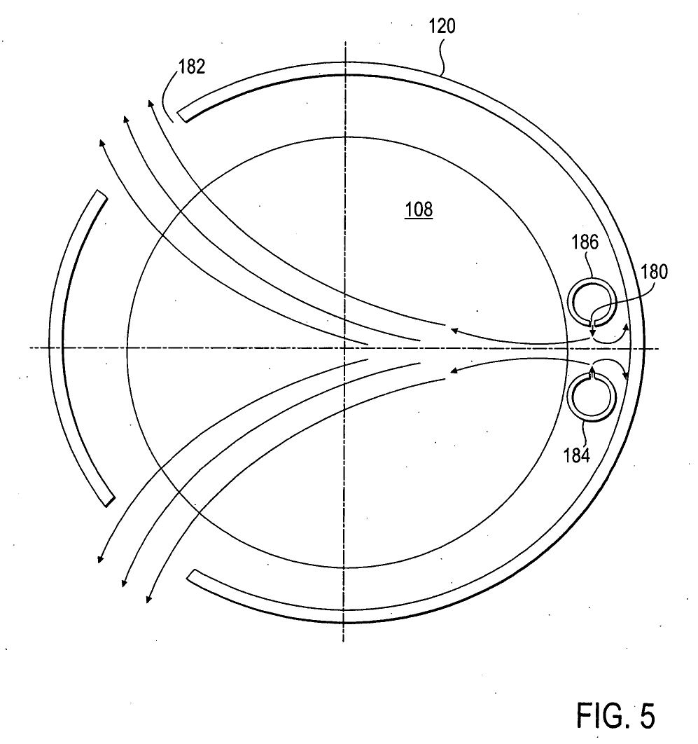

FIG. 5 is another plan view of a portion of the thermal processing system 100 of FIG. 1 taken along the line A-A of FIG. 1 showing an alternative gas flow path from the orifices 180 of the primary and secondary injector 184, 186, across an illustrative on of the wafer 108 and to the exhaust slots 182 according to yet another embodiment. Thus, as will be appreciated by those of ordinary skill in the art, a variety of gas flow paths may be achieved within the teaching of embodiments of the present invention. Additionally, while injector 116 is shown comprised of primary and secondary injectors 184 and 186, injector 116 may be comprised of a single injection tube.

While the across flow technology is described with reference to a batch vertical furnace, it is to be understood that the across flow technology can be practiced in a single wafer system as well. In such a system, the precursors are conveyed in across-flow type manner over the top surface of the single substrate. Embodiments of the method described herein in a single wafer system may be carried out in such across flow manner.

Methods are also carried out in a single wafer thermal processing system to deposit a silicon-nitrogen. containing dielectric film on a wafer. Typically, the system comprises a single wafer process chamber used to support a single silicon wafer, such as a 300 mm substrate. The wafer is loaded into the process chamber and the pressure is reduced to <10,000 mTorr. The temperature is controlled to between 100° C. and 500° C. In this embodiment, an ALD process is employed and is initialed by flowing between 1 and 50 sccm of “trisilylamine” (TSA) and allowed to form a monolayer on the wafer. Excess amounts of TSA are removed by purging with N₂. A nitrogen containing reactant such as NH₃ is introduced to the process chamber by flowing between 50 sccm and 1000 sccm of NH₃. The NH₃ reacts with the monolayer of TSA to form a silicon-nitrogen dielectric layer. Excess amounts of NH₃ are removed by purging with N₂. Typically, total gas flows throughout the process are less than 20,000 sccm. This results in the deposition of a silicon-nitrogen dielectric layer with an effective deposition rate of between 0.2 and 5.0 A per cycle. This sequence is repeated until the desired thickness of the silicon-nitrogen dielectric film is deposited. The wafer is then removed from the process chamber.

Alternatively, the above methods are carried out using chemical vapor deposition. In this embodiment, TSA and the nitrogen containing reactant precursors, such as NH₃, are conveyed together to the chamber, where they react and form the desired film on the surface of the wafer(s). The flowrate of TSA is in the range of approximately 1 sccm and 100 sccm, and the flowrate of NH₃ is in the range of approximately 50 sccm and 10,000 sccm. The deposition temperature is typically in the range of approximately 300-800° C., and preferably at 550° C. and below. This process sequence can be used to deposit high quality silicon-nitrogen dielectric films with a within-wafer uniformity of <3% 3-sigma, a wafer-to-wafer uniformity of <3% 3-sigma, a silicon to nitrogen ratio [Si:N] of between 0.65 and 0.85, and a refractive index of between 1.9 and 2.1.

The methods described herein may be carried out in either equipment platform, i.e. in either a single wafer thermal processing system or a batch thermal processing system.

In another embodiment of the present invention TSA is used to deposit a silicon-oxygen containing dielectric film on a substrate or wafer. The deposition may be accomplished using either ALD or CVD techniques. The process chamber can be adapted to hold a single substrate or the process chamber can be adapted to hold a plurality of substrates. The substrate is controlled to a desired temperature, typically 550° C. or less, and most preferably 400° C. or less, and in some embodiments the temperature is in the range of approximately 150-550° C. The pressure in the process chamber is controlled to a desired pressure, typically between 0.01 mTorr and 760 Torr, most preferably less than 10 Torr. When depositing by ALD, TSA precursor is introduced into the process chamber and allowed to form a monolayer on the surface of the substrate(s). Excess amounts of TSA precursor are removed from the process chamber. An oxygen containing reactant is introduced into the process chamber and allowed to react with the monolayer of TSA that was previously formed on the substrate(s). Examples of suitable oxygen containing reactants comprise oxygen (O₂), ozone (O₃), water vapor (H₂O), hydrogen peroxide (H₂O₂) and the like. The reaction of the oxygen containing reactant with TSA forms a silicon-oxygen dielectric film on the substrate(s). Excess amounts of the oxygen containing reactant are removed from the process chamber. This sequence is repeated until the desired thickness of the silicon-oxygen dielectric material is deposited on the substrate(s). When depositing the silicon oxide film by CVD, the substrate is controlled at a deposition temperature, typically 550° C. or less, and most preferably 400° C. or less, and in some embodiments the temperature is in the range of approximately 150-550° C. TSA and an oxygen containing reactant precursor are conveyed to the chamber where the precursors react and form a silicon-oxygen film on the surface of the substrate. Deposition is carried out until the desired film thickness is achieved.

In either embodiment, the precursor(s) may be conveyed to the substrate in a cross-flow manner, that is the precursor is injected near one peripheral region of the substrate, and flows across the surface of the substrate, where the precursor(s) then exits at an opposite peripheral region of the substrate.

In another example, a vertical furnace configured to hold a plurality of silicon wafers, such as 300 m m wafers, deposit a silicon-oxygen containing dielectric film. Typically the wafers number between 1 and 100 for a single batch process. In some embodiments the preferred vertical furnace technology includes the across-flow technology as described above. The wafers are loaded into the furnace and the pressure is reduced to <10,000 mTorr. The temperature is controlled to between 100° C. and 500° C. When depositing the silicon oxide film by CVD, TSA and an oxygen containing reactant precursor, such O₃ or O₂, are conveyed to the chamber concurrently. The precursors react and form a silicon-oxygen film on the surface of the substrate. The flowrate of TSA is typically between 1 sccm and 100 sccm, and the flow rate of O₃ or O₂ is in the range of about 500 sccm and 10,000 sccm. Deposition is carried out until the desired film thickness is achieved. This process sequence can be used to deposit high quality silicon-oxygen dielectric films with a within-wafer uniformity of <3% 3-sigma, a wafer-to-wafer uniformity of <3% 3-sigma, a silicon to oxygen ratio [Si:O] of between 0.25 to 0.45, and a refractive index of between 1.40 and 1.50.

When employing ALD, the process is initialed by flowing between 1 sccm and 100 sccm of “trisilylamine” (TSA) and allowed to form a monolayer on the wafers. Excess amounts of TSA are removed by purging with N₂. An oxygen containing reactant such as O₃ or O₂ is introduced to the process chamber by flowing between 50 sccm and 10,000 sccm of O₃. The O₃ reacts with the monolayer of TSA to form a silicon-oxygen dielectric layer. Excess amounts of the O₃ are removed by purging with N₂. Typically, total gas flows throughout the process are less than 20,000 sccm. This results in the deposition of a silicon-oxygen dielectric layer with an effective deposition rate of between 0.2 and 5 A per cycle. This sequence is repeated until the desired thickness of the silicon-oxygen dielectric film is deposited. The pressure in the process chamber is then increased to one atmosphere and the wafers are removed from the process chamber.

In either embodiments the precursor(s) may be conveyed to the substrate in a cross-flow manner, that is the precursor is injected near one peripheral region of the substrate, and flows across the surface of the substrate, where the precursor(s) then exits at an opposite peripheral region of the substrate.

In further examples a single wafer process chamber is used to hold a single silicon wafer, such as a 300 mm wafer, to deposit a silicon-oxygen containing dielectric film on the surface of the wafer. The wafer is loaded into the process chamber and the pressure is reduced to <10,000 mTorr. The temperature is controlled to between 100° C. and 500° C. When using ALD, the process is initialed by flowing between 1 sccm and 50 sccm of “trisilylamine” (TSA) and allowed to form a monolayer on the wafer. Excess amounts of TSA are removed by purging with N₂. An oxygen containing reactant such as O₃ or O₂ is introduced to the process chamber by flowing between 50 sccm and 1000 sccm of O₃. The O₃ reacts with the monolayer of TSA to form a silicon-oxygen dielectric layer. Excess amounts of the O₃ are removed by purging with N₂. Typically, total gas flows throughout the process are less than 20,000 sccm. This results in the deposition of a silicon-oxygen dielectric layer with an effective deposition rate of between 0.2 and 5.0 A per cycle. This sequence is repeated until the desired thickness of the silicon-oxygen dielectric film is deposited. The wafer is removed from the process chamber. When depositing the silicon oxide film by CVD, TSA and an oxygen containing reactant precursor, such O₃ or O₂, are conveyed to the chamber concurrently. The precursors react and form a silicon-oxygen film on the surface of the substrate. The flowrate of TSA is typically between 1 sccm and 100 sccm, and the flow rate of O₃ or O₂ is in the range of about 500 sccm and 10,000 sccm. Deposition is carried out until the desired film thickness is achieved. In either process, the precursor(s) may be conveyed to the substrate in a cross-flow manner, that is the precursor is injected near one peripheral region of the substrate, and flows across the surface of the substrate, where the precursor(s) then exits at an opposite peripheral region of the substrate.

In another embodiment of the present invention, TSA is used as a precursor to deposit a silicon-nitrogen-oxygen containing dielectric film on a substrate. In one embodiment, the deposition is accomplished using ALD. Alternatively, the method may be carried out by CVD techniques. The process chamber is adapted to hold a single substrate or the process chamber can be adapted to hold a plurality of substrates. The substrate is controlled to a desired temperature, typically 550° C. or less, and most preferably 400° C. or less. The pressure in the process chamber is controlled to a desired pressure, typically between 0.01 mTorr and 760 Torr, most preferably less than 10 Torr. When depositing the silicon-nitrogen-oxygen film by CVD, TSA, and an oxygen/nitrogen containing reactant precursor are conveyed concurrently to the process chamber. The reactants react and form a film on the surface of the substrate. Examples of suitable oxygen and nitrogen containing reactants comprise nitrous oxide (N₂O), nitric oxide (NO), nitrogen dioxide (NO₂), and the like. Alternatively, two separate compounds may provide the oxygen and nitrogen constituents. Deposition is carried out until the desired film thickness is achieved. In an ALD embodiment, TSA precursor is introduced into the process chamber and allowed to form a monolayer on the surface of the substrate(s). Excess amounts of TSA precursor are removed from the process chamber. An oxygen and nitrogen containing reactant is introduced into the process chamber and allowed to react with the monolayer of TSA that was previously formed on the substrate(s). Examples of suitable oxygen and nitrogen containing reactants comprise nitrous oxide (N₂O), nitric oxide (NO), nitrogen dioxide (NO₂), and the like. The reaction of the oxygen and nitrogen containing reactant with TSA forms a silicon-nitrogen-oxygen dielectric film on the substrate(s). Excess amounts of the oxygen and nitrogen containing reactant are removed from the process chamber. This sequence is repeated until the desired thickness of the silicon-nitrogen-oxygen dielectric material is deposited on the substrate(s).

In other embodiments, a vertical furnace is used to hold a plurality of silicon wafers is used to form a silicon-nitrogen-oxygen containing dielectric film on the wafers. Typically the wafers number between 1 and 100 for a single batch process. In some embodiments the preferred vertical furnace technology includes the beneficial “across-flow” technology as above. The wafers are loaded into the furnace and the pressure is reduced to <10,000 mTorr. The temperature is controlled to between 100° C. and 500° C. When using ALD to deposit the film, the process is initialed by flowing between 1 sccm and 100 sccm of “trisilylamine” (TSA) and allowed to form a monolayer on the wafers. Excess amounts of TSA are removed by purging with N₂. A nitrogen-oxygen containing reactant such as N₂O (or a mixture of reactants such as NH₃ and O₂) is introduced to the process chamber by flowing between 50 sccm and 10,000 sccm of N₂O. The N₂O reacts with the monolayer of TSA to form a silicon-nitrogen-oxygen dielectric layer. Excess amounts of the N₂O are removed by purging with N₂. Typically, total gas flows throughout the process are less than 20,000 sccm. This results in the deposition of a silicon-nitrogen-oxygen dielectric layer with an effective deposition rate of between 0.2 and 5.0 A per cycle. This sequence is repeated until the desired thickness of the silicon-nitrogen-oxygen dielectric film is deposited. The pressure in the process chamber is then increased to one atmosphere and the wafers are removed from the process chamber.

Alternatively, a single wafer process chamber is used to hold a single silicon wafer to form a silicon-nitrogen-oxygen containing dielectric film on the surface of the wafer. The wafer is loaded into the process chamber and the pressure is reduced to <10,000 mTorr. The temperature is controlled to between 100° C. and 500° C. When employing ALD, the process is initialed by flowing between 1 sccm and 50 sccm of “trisilylamine” (TSA) and allowed to form a monolayer on the wafer. Excess amounts of TSA are removed by purging with N₂. A nitrogen-oxygen containing reactant such as N₂O (or a mixture of reactants such as NH₃ and O₂ is introduced to the process chamber by flowing between 50 sccm and 1000 sccm of N₂O. The N₂O reacts with the monolayer of TSA to form a silicon-nitrogen-oxygen dielectric layer. Excess amounts of the N₂O are removed by purging with N₂. Typically, total gas flows throughout the process are less than 20,000 sccm. Alternatively either simultaneously or sequentially with the oxygen containing reactant, a nitrogen containing reactant such as NH₃ or N₂O is introduced into the process chamber by flowing between 50 sccm and 10,000 sccm of NH₃. The NH₃ reacts with the monolayer of TSA to form a silicon-nitrogen dielectric layer. Excess amounts of the NH₃ are removed by purging with N₂. If the two reactants are introduced sequentially, either the oxygen containing or nitrogen containing reactant may be introduced first. This sequence is repeated until the desired thickness of the silicon-nitrogen-oxygen dielectric film is deposited. The wafer is removed from the process chamber.

In an alternative embodiment TSA precursor is introduced into the process chamber sequentially or concurrently with a separate oxygen containing reactant and a nitrogen containing reactant, depending upon whether the process is carried out by CVD or ALD. When employing CVD, deposition is started by conveying TSA, and oxygen containing reactant, and a nitrogen containing reactant, all to the process chamber. The reactants all react and form a layer of silicon-oxygen-nitrogen on the surface of the substrate. Suitable oxygen reactants include O₃. Suitable nitrogen reactants include NH₃ and N₂O. Deposition continues until the desired thickness of the film is achieved. This process sequence can be used to deposit high quality silicon-nitrogen-oxygen dielectric films with a within-wafer uniformity of <3% 3-sigma, a wafer-to-wafer uniformity of <3% 3-sigma, a silicon to nitrogen to oxygen ratio [Si:N:O] of about 1:1:1, and a refractive index of between 1.40 and 1.70.

Examples of suitable oxygen containing reactants comprise oxygen (O₂), ozone (O₃), water vapor (H₂O), nitrous oxide (N₂O), nitric oxide (NO), nitrogen dioxide (NO₂), and the like. Examples of suitable nitrogen containing reactants comprise ammonia (NH₃), hydrazine (N₂H₄), nitrous oxide (N₂O), nitric oxide (NO), nitrogen dioxide (NO₂), and the like. The reaction of the oxygen containing reactant and the nitrogen containing reactant with the TSA forms a silicon-nitrogen-oxygen dielectric film on the substrate(s). This is carried out until the desired thickness of the silicon-nitrogen-oxygen dielectric material is deposited on the substrate(s).

In either embodiments the precursor(s) may be conveyed to the substrate in a cross-flow manner, that is the precursor is injected near one peripheral region of the substrate, and flows across the surface of the substrate, where the precursor(s) then exits at an opposite peripheral region of the substrate.

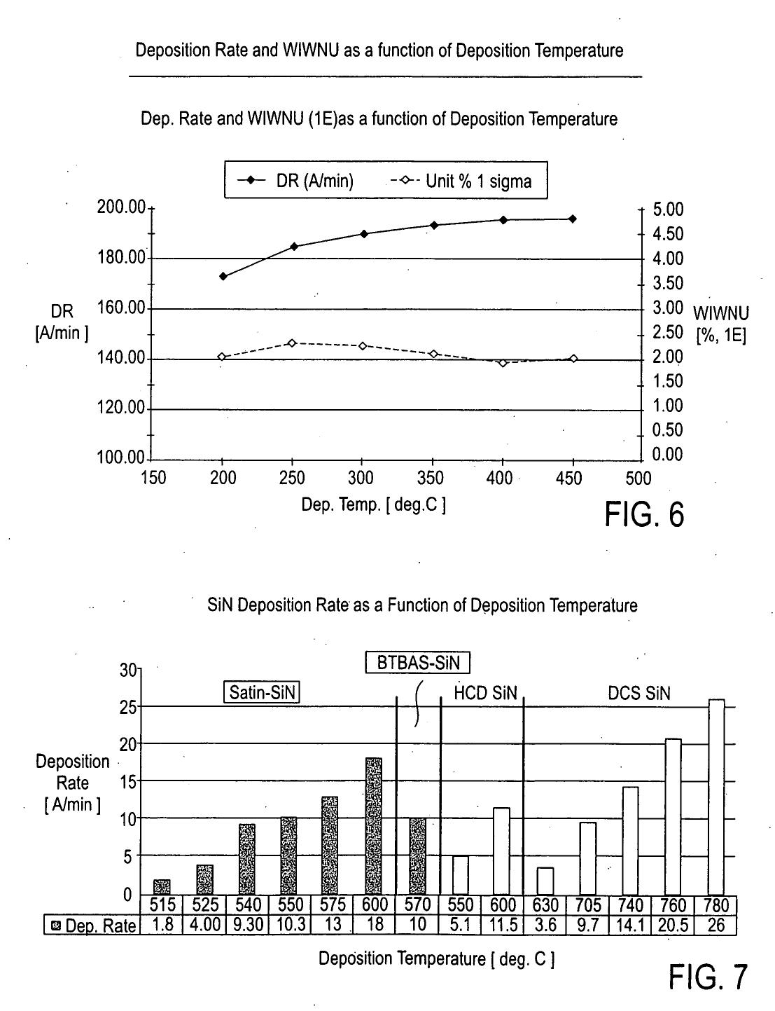

Films deposited according to embodiments of the present invention were tested for certain properties. FIG. 6 is a graph illustrating the deposition rate and within-wafer uniformity (WIWNU) as a function of deposition temperature for silicon oxide films deposited by CVD in a single wafer thermal processing apparatus according to some embodiments of the method of the present invention. The method was carried out using TSA flowrate of 11 sccm and an oxygen flowrate of 200 sccm. The pressure was maintained at 7 Torr. As shown in the data, high deposition rates of greater than 180 A/min are achieved at temperatures below 500° C., while the films exhibit good quality uniformity.

FIG. 7 is a graph showing certain properties for silicon nitride films deposited by CVD in a batch thermal processing apparatus according to different embodiments of the present invention. Silicon nitride deposition rate as a function of deposition temperature for silicon nitride films deposited in a batch thermal processing apparatus is shown on the far left of the graph. These results are compared to deposition carried out with other precursors, namely BTBAS, HCD and DCS.

The foregoing descriptions of specific embodiments of the present invention have been presented for the purpose of illustration and description. They are not intended to be exhaustive or to limit the invention to the precise forms disclosed, and obviously many modifications, embodiments, and variations are possible in lights of the above teaching. It is intended that the scope of the invention be defined by the Claims appended hereto and their equivalents.

What is claimed is:

1. A method of forming a silicon containing film on the surface of one or more substrates, characterized in that: a silylamine moiety and one or more reactant precursors are reacted in a process chamber by flowing the silylamine moiety and the one or more reactant precursors across a top surface of the one or more substrates to form a film thereon.

2. The method of claim 1 wherein the method is carried out at a deposition temperature of less than 550° C.

3. The method of claim 1 wherein said silylamine moiety is comprised of the formula:
HₘN(SiH₃)ₙ
where n is an integer from 1 to 3 and m is equal to 3−n.

4. The method of claim 1 wherein said silylamine moiety is comprised of the formula:
HₘN(Si₂H₅)ₙ
where n is an integer from 1 to 3 and m is equal to 3−n.

5. The method of claim 1 wherein a silicon oxide film is formed on the surface of the substrate and the method is carried out a deposition temperature in the range of approximately 150-550° C.

6. The method of claim 1 wherein a silicon nitride film is formed on the surface of the substrate and the method is carried out a deposition temperature in the range of approximately 300-800° C.,

7. The method of claim 6 wherein the deposition temperature is in the range of approximately 500-520° C.

8. The method of claim 1 where the silylamine moiety and precursors are flowed into the process chamber concurrently.

9. The method of claim 1 where the silylamine moiety and precursors are flowed into the process chamber sequentially.

10. A method of forming a silicon containing film on one or more substrates in a process chamber comprising: conveying to the process chamber, either sequentially or concurrently, a precursor comprising a silylamine moiety and at least one reactant containing nitrogen to form a silicon-nitrogen film on the surface of one or more substrates.

11. The method of claim 10 wherein the process chamber is configured to contain a single substrate.

12. The method of claim 10 wherein the process chamber is configured to contain a plurality of substrates.

13. The method of claim 10 wherein:
the method is performed at a temperature in the range of approximately 300 to 800° C.;
at a pressure between 0.01 mTorr and 760 Torr; and
using total precursor flow rates between 0 and 20,000 sccm.

14. The method of claim 10 wherein said silylamine moiety is comprised of the formula:
HₘN(SiH₃)ₙ
where n is an integer from 1 to 3 and m is equal to 3−n.

15. The method of claim 10 wherein said silylamine moiety is comprised of the formula:
HₘN(Si₂H₅)ₙ
where n is an integer from 1 to 3 and m is equal to 3−n.

16. The method of claim 10 wherein the silylamine moiety and the at least one reactant precursor, are flowed concurrently and across a top surface of the one or more substrates to form a film thereon.

17. The method of claim 10 wherein the deposition temperature is in the range of approximately 500-550° C.

18. A method of forming a silicon containing film on one or more substrates in a process chamber comprising: conveying to a process chamber, either sequentially or concurrently, a precursor comprising a silylamine moiety and at least one reactant containing oxygen to form a silicon-oxygen film on the one or more substrates.

19. The method of claim 18 wherein the process chamber is configured to contain a single substrate.

20. The method of claim 18 wherein the process chamber is configured to contain a plurality of substrates.

21. The method of claim 18 wherein:
the method is performed at a temperature of less than 550° C.;
at a pressure between 0.01 mTorr and 760 Torr; and
using total precursor flow rates between 0 and 20,000 sccm.

22. The method of claim 18 wherein said silylamine moiety is comprised of the formula:
HₘN(SiH₃)ₙ
where n is an integer from 1 to 3 and m is equal to 3−n.

23. The method of claim 18 wherein said silylamine moiety is comprised of the formula:
HₘN(Si₂H₅)ₙ
where n is an integer from 1 to 3 and m is equal to 3−n.

24. The method of claim 18 wherein the silylamine moiety and the at least one reactant, are flowed concurrently and across a top surface of the one or more substrates to form a film thereon.

25. The method of claim 18 wherein the method is carried out at a deposition temperature in the range of approximately 150-550° C.

26. A method of forming a film on one or more substrates in a process chamber comprising:
conveying a first precursor comprising a silylamine moiety to the process chamber sequence to form a first layer on the substrate;
conveying a second reactant containing both nitrogen and oxygen to react with the first layer to form a silicon-nitrogen-oxygen film; and
repeating the above steps until the desired thickness of the silicon-nitrogen-oxygen film is formed.

27. The method of claim 26 wherein the process chamber is configured to contain a single substrate.

28. The method of claim 26 wherein the process chamber is configured to contain a plurality of substrates.

29. The method of claim 26 wherein:
the method is performed at a temperature of less than 550° C.;
at a pressure between 0.01 mTorr and 760 Torr; and
using total precursor flow rates between 0 and 20,000 sccm.

30. A method comprising: conveying, either sequentially or concurrently, a first precursor comprising a silylamine moiety to the process chamber a second reactant containing nitrogen and a third reactant containing oxygen to form a silicon-nitrogen-oxygen film.

31. The method of claim 30 wherein the process chamber is configured to contain a single substrate.

32. The method of claim 30 wherein the process chamber is configured to contain a plurality of substrates.

33. The method of claim 30 wherein:
the method is performed at a temperature of less than 550° C.;
at a pressure between 0.01 mTorr and 760 Torr; and
using total precursor flow rates between 0 and 20,000 sccm.

34. The method of claim 30 where the silylamine moiety, the second reactant containing nitrogen and the third reactant containing oxygen are conveyed concurrently and flow across a top surface of the one or more substrates to form a film thereon.
